(19) United States
(12) Patent Application Publication
(10) Pub. No.: US 2009/0285082 A1
(43) Pub. Date: Nov. 19, 2009

(54) ELECTRIC FIELD READ/WRITE HEAD, METHOD OF MANUFACTURING THE ELECTRIC FIELD READ/WRITE HEAD, AND INFORMATION STORAGE DEVICE INCLUDING THE ELECTRIC FIELD READ/WRITE HEAD

(75) Inventors: Hyoung-soo KO, Seoul (KR); In-kyeong YOO, Yongin-si (KR); Ju-hwan JUNG, Seoul (KR); Chul-min PARK, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/251,072

(22) Filed: Oct. 14, 2008

(30) Foreign Application Priority Data
May 16, 2008 (KR) 10-2008-0045522

(51) Int. Cl. G11B 9/00; H01L 21/00

(52) U.S. Cl. 369/126; 438/3; G9B/9; 257/E21.001

(57) ABSTRACT

An electric field head includes a body portion and a read head having a channel layer provided on an air bearing surface (ABS) of the body portion facing a recording medium and a source and a drain contacting both ends of the channel layer. The electric field head is manufactured by defining a head forming portion of a substrate, separating the head forming portion from the substrate, forming an ABS pattern on a side surface of the separated head forming portion, and forming a channel layer for a read head on a surface of the head forming portion where the ABS pattern is formed. An information storage device includes a ferroelectric recording medium and the electric field head.

### CROSS-REFERENCE TO RELATED PATENT APPLICATIONS

This application claims priority from Korean Patent Application No. 10-2008-0045522, filed on May 16, 2008, in the Korean Intellectual Property Office, the disclosure of which is incorporated herein in its entirety by reference.

### BACKGROUND OF THE INVENTION

1. Field of the Invention

Apparatuses and method consistent with the present invention relate to a read/write head and an information storage device, and more particularly, to an electric field read/write head, a method of manufacturing the electric field read/write head, and an information storage device comprising the electric field read/write head.

2. Description of the Related Art

Hard disk drives (HDDs) generally use a magnetic recording method. However, since a magnetic field has a loop shape, it is difficult to generate a strong local magnetic field using a magnetic recording type read/write head (hereinafter, referred to as a magnetic read/write head). Accordingly, due to such a limitation, it is difficult to increase a recording density using the magnetic recording method.

To overcome this limitation of the recording density in the conventional HDD, studies have been conducted regarding a read/write head using an electric field (hereinafter, referred to as an electric field read/write head) and a ferroelectric recording medium on which data is recorded using an electric field. The electric field read/write head includes a scanning probe having a field effect transistor channel structure or a scanning probe having a resistive tip. Since scanning probe microscope (SPM) technology using the scanning probe enables the generation of energy (electric field) that is stronger and more localized than that in the magnetic recording method, the recording density can be increased over 1 Tb/in².

However, the electric field recording method based on the SPM technology has a problem related to friction and abrasion on a contact surface between a sharp probe and a recording medium. Also, in order to implement a compact and large capacity information storage device by using a probe type head, several thousand probe arrays must be formed, and the recording medium must be linearly moved to precisely track over the thousands of probe arrays on the recording medium. In such an implementation, during a writing operation, signals must be applied separately to each probe, and during a reading operation, signals from the respective probes must be processed separately. These restrictive elements prohibit the realization of a compact and large capacity data storage device that uses electric field writing based on the SPM technology.

Thus, there is a demand for an information storage device using an electric field recording method adopting a drive mechanism that is more stable and reliable and using a read/write head which can solve the above problems due to the use of the probe.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides an electric field head capable of read and write functions utilizing an electric field and a manufacturing method thereof.

Also, the present invention provides an information storage device comprising the electric field head.

According to an aspect of the present invention, an electric field head comprises a body portion and a read head having a channel layer provided on an air bearing surface (ABS) of the body portion facing a recording medium and a source and a drain contacting both ends of the channel layer.

The electric field head further comprises a write head provided on a surface of the body portion that is perpendicular to the ABS. The channel layer comprises any one of carbon nanotube (CNT), graphene, and semiconductor nanowire. The source and the drain extend from the ABS to a surface perpendicular to the ABS. The source and the drain may be a metal region or a doping region. The source and the drain may be a metal layer provided on the ABS. The source and the drain may be a metal layer provided in the ABS.

According to another aspect of the present invention, a method of manufacturing an electric field head comprises defining a head forming portion of a substrate, separating the head forming portion from the substrate, forming an ABS pattern on a side surface of the separated head forming portion, and forming a channel layer for a read head on a surface of the head forming portion where the ABS pattern is formed.

The method further comprises forming a write head on the head forming portion before the head forming portion is separated from the substrate. The head forming portion comprises a plurality of head forming regions. The channel layer is formed of any one of CNT, graphene, and semiconductor nanowire. The read head comprises a source and a drain contacting both ends of the channel layer.

According to another aspect of the present invention, an information storage device comprises a ferroelectric recording medium and an electric field head, wherein the electric field head comprises a body portion and a read head having a channel layer provided on an ABS of the body portion facing a recording medium and a source and a drain contacting both ends of the channel layer.

The information storage device further comprises a write head provided on a surface of the body portion that is perpendicular to the ABS. The channel layer comprises any one of CNT, graphene, and semiconductor nanowire. The source and the drain extend from the ABS to a surface perpendicular to the ABS. The source and the drain may be a metal region or a doping region. The source and the drain may be a metal layer provided on the ABS surface. The source and the drain may be a metal layer provided in the ABS surface. The ferroelectric recording medium may be of a rotating disc type and the electric field head pivots by flying over a surface of the recording medium.

### BRIEF DESCRIPTION OF THE DRAWINGS

The above and other aspects of the present invention will become more apparent by describing in detail exemplary embodiments thereof with reference to the attached drawings in which:

FIGS. 1 and 2 are perspective views of electric field read/write heads according to exemplary embodiments of the present invention;

FIGS. 3A to 3E are perspective views for explaining a method of manufacturing an electric field read/write head according to an exemplary embodiment of the present invention; and

FIG. 4 is a perspective view of an information storage device comprising the electric field read/write head according to an exemplary embodiment of the present invention.

### DETAILED DESCRIPTION OF EXEMPLARY EMBODIMENTS OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

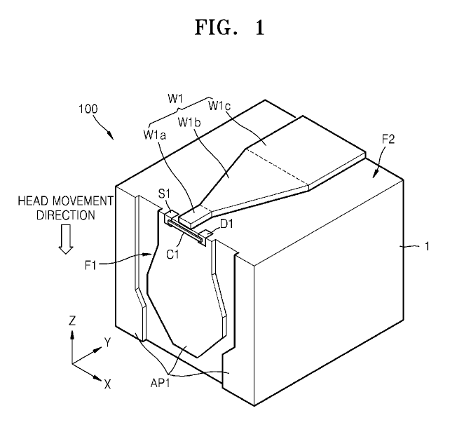

FIG. 1 is a perspective view of an electric field read/write head 100 according to an exemplary embodiment of the present invention.

Referring to FIG. 1, a channel layer C1 is provided on a surface of a body portion 1 facing a recording medium, that is, an ABS (hereinafter, referred to as a first face) F1. The channel layer C1 may be parallel to the first face F1 on the first face F1. That is, the channel layer C1 may be separately provided on the first face F1 of the body portion 1, rather than having a channel region provided inside the body portion 1. The channel layer C1 may be provided on the first face F1 perpendicular to a direction in which the electric field read/write head 100 moves. The channel layer C1 is a semiconductor layer and the electric resistance of the channel layer C1 may vary according to an electric field applied externally, that is, from a recording medium. The channel layer C1 may be formed of, for example, CNT or graphene, semiconductor nanowire such as Si nanowire, or other semiconductor materials. A source S1 and a drain D1 are provided to contact both ends of the channel layer C1. The source S1 and the drain D1 with the channel layer C1 may constitute a read head. The source S1 and the drain D1 are conductive regions and may be metal regions or semiconductor regions doped with conductive impurities, that is, a doping region. The side surfaces and upper surfaces of the source S1 and the drain D1 may be exposed at a first side portion of the body portion 1. The first side portion may be a portion where the first face F1 meets a second face F2 perpendicular to the first face F1, that is, the upper surface of the body portion 1. In other words, the source S1 and the drain D1 may be regions extending from the first face F1 to the second face F2. The channel layer C1 may be provided to contact the exposed surfaces of the source S1 and the drain D1. A contact electrode (not shown) contacting each of the exposed upper surfaces of the source S1 and the drain D1 may be further provided.

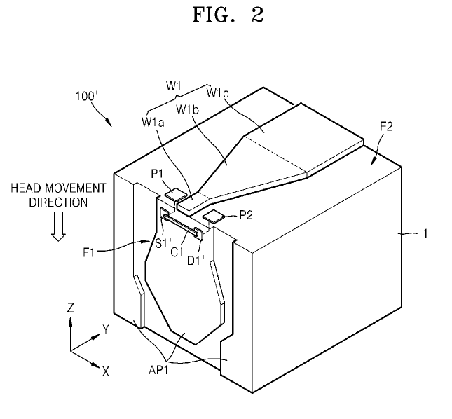

Although not shown, a capping metal layer covering opposite ends the channel layer C1 may be further provided on the exposed side surfaces of the source S1 and the drain D1. Since the capping metal layer contacts the source S1 and the drain D1 by encompassing both ends of the channel layer C1, the electric resistance between the channel layer C1 and the source S1 and the drain D1 may be reduced by the capping metal layer. The structure of the source S1 and the drain D1 and the positional relationship between the source S1 and the drain D1 and the channel layer C1 may vary differently, which will be described later in detail with reference to FIG. 2.

An ABS pattern AP1 may be provided on the first face F1 of the body portion 1. The ABS pattern AP1 may be formed by etching, that is, recessing, a predetermined region of the first face F1 by a given thickness. Although the ABS pattern AP1 may be referred to as a pattern including both the etched region and the region that is not etched so as to be relatively protruding, only the protruding region is defined to be the ABS pattern AP1 for the convenience of explanation. The ABS pattern AP1 enables the electric field read/write head 100 to fly over the surface of the recording medium. The shape of the ABS pattern AP1 as shown in FIG. 1 is merely an example and may be changed diversely. The channel layer C1 may be provided at the center of the upper end portion of the ABS pattern AP1. Although the channel layer C1, the source S1, and the drain D1 are exaggerated in drawings, they are actually significantly smaller than the body portion 1 and the ABS pattern AP1. Thus, the recessed region of the first face F1 does not matter in forming the channel layer C1, the source S1, and the drain D1.

A write head W1 may be further provided on the upper surface of the body portion 1, that is, the second face F2. The write head W1 may be provided at the center portion of the second face F2 to be parallel to a Y axis. The write head W1 may include first through third portions W1a-W1c which are connected in series. The first portion W1a may be adjacent to the first face F1 and have a relatively narrow width. The width of the second portion W1b gradually increases from the first portion W1a to the third portion W1c. The width of the third portion W1c may be greater than that of the first portion W1a. The structure of the write head W1 is not limited thereto and may vary in different ways.

FIG. 2 is a perspective view of an electric field read/write head 100′ according to another exemplary embodiment of the present invention.

Referring to FIG. 2, a source S1′ and a drain D1′ are provided on the first face F1. The channel layer C1 connecting the source S1′ and the drain D1′ may be provided on the source S1′ and the drain D1′. A first electrode pad P1 electrically connected to the source S1′ and a second electrode pad P2 electrically connected to the drain D1′ may be provided on the second face F2. The source S1′ and the first electrode pad P1, and the drain D1′ and the second electrode pad P2, may be electrically connected to each other via an elbow type conductive plug provided in the body portion 1, as indicated by a dotted line. The shapes of the first and second electrode pads P1 and P2 may vary. The structure of a means for connecting the source S1′ and the first electrode pad P1, and the drain D1′ and the second electrode pad P2, may vary. Although it is not illustrated, a capping metal layer covering both ends of the channel layer C1 may be further provided on the source S1′ and the drain D1′. Also, instead of providing the channel layer C1 on the source S1′ and the drain D1′, the channel layer C1 may be first provided on the first face F1 and then the source S1′ and the drain D1′ may be provided to cover both ends of the channel layer C1. Furthermore, instead of providing the source S1′ and the drain D1′ on the first face F1, a groove may be formed in the first face F1 and the groove filled with metal, thereby forming the source S1′ and the drain D1′. That is, the source S1′ and the drain D1′ may be formed as a metal layer in the first face F1.

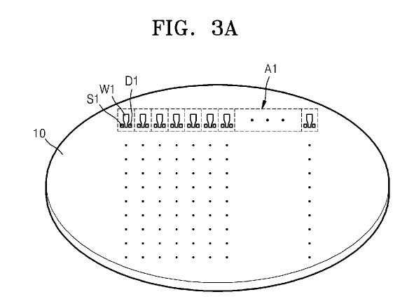

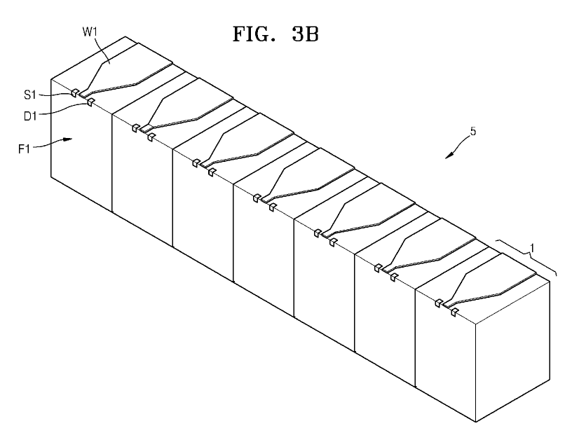

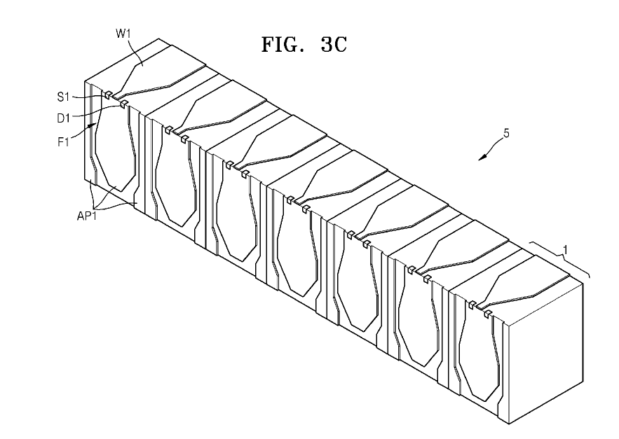

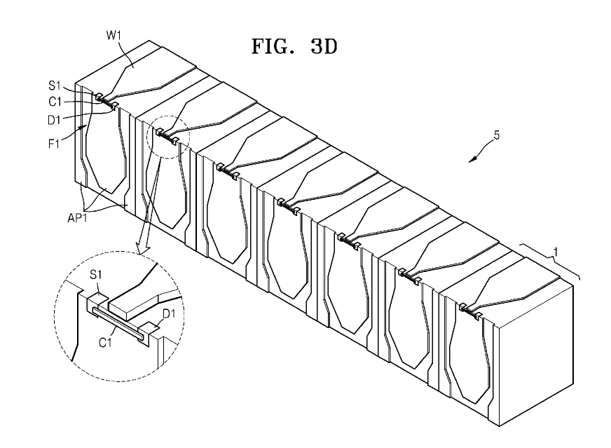

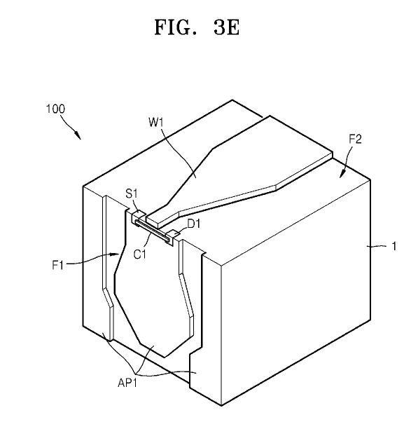

FIGS. 3A to 3E are perspective views for explaining a method of manufacturing an electric field read/write head according to an exemplary embodiment of the present invention.

Referring to FIG. 3A, a plurality of write heads W1 are formed on a substrate 10. The substrate 10 may be, for example, a silicon wafer or other types of a substrate. The write heads W1 are arranged corresponding to a head forming region, to regularly form a plurality of rows and columns. A first region A1 may be a head forming portion including a plurality of the head forming regions and the head forming portion may be arranged in multiple numbers. A source S1 and a drain D1 may be formed at the sides of each write head W1 before or after the write heads W1 are formed. The source S1 and the drain D1 are formed by doping conductive impurities in the substrate 10 or forming a plurality of grooves in the substrate 10 and then filling the grooves with a metal material.

Referring to FIG. 3B, a bar type block body portion 5 is obtained by dividing the substrate 10. The block body portion 5 may include a plurality of unit body portions 1 that are arranged linearly. Each of the unit body portions 1 may include the write head W1 and the source S1 and the drain D1 at the sides of the write head W1. A side surface of the block body portion 5, that is, one of the sliced surfaces (hereinafter, referred to as the first face) F1, on which the ABS pattern AP1 (referring to FIG. 3C) is to be formed, undergoes various mechanical processes such as grinding and lapping. The first face F1 may contact an end of the write head W1 having a narrow width. During the mechanical process of forming the first face F1, there may be loss of parts of the write head W1, the source S1, and the drain D1 exposed on the first face F1.

Referring to FIG. 3C, an ABS pattern AP1 is formed on the first face F1 of each unit body portion 1. The process of forming the ABS pattern AP1 may be a process of etching a predetermined region of the first face F1 to a predetermined depth.

Referring to FIG. 3D, a channel layer C1 is formed on the first face F1 of each unit body portion 1. The channel layer C1 is singularly formed on the ABS pattern AP1 of each unit body portion 1 to connect the source S1 and the drain D1. The channel layer C1 may be formed of CNT, graphene, or semiconductor nanowire. In the method of forming the channel layer C1 using the CNT, a mask film having an aperture to expose a channel layer forming region is formed on the first face F1. The CNT is provided on the mask film and the channel layer forming region and then the mask film is removed. When the mask film is removed, the CNT existing on the mask film is removed also so that the CNT remains only in the channel layer forming region. The mask film may be, for example, an octadecyltrichlosilane (OTS) film. Instead of this method, the channel layer C1 formed of the CNT may be formed using a growth method using catalyst.

When the channel layer C1 is formed of graphene, a growth method or an exfoliation method may be used. When the channel layer C1 is formed using the nanowire, a method of attaching semiconductor nanowire manufactured on another substrate on a given position of the ABS pattern AP1 may be used. Since a method of synthesizing graphene or semiconductor nanowire is well known, detailed description thereof will be omitted herein. The method of forming the channel layer C1 is not limited thereto. That is, the channel layer C1 may be formed of other semiconductor materials, in addition to the CNT, graphene, and semiconductor nanowire, using a variety of methods. After the channel layer C1 is formed, a thermal treatment process may be further performed to reduce contact resistance of the source S1, the drain D1, and the channel layer C1. Then, a capping metal layer (not shown) covering the channel layer C1 is formed on the source S1 and the drain D1. Next, the electric field read/write head 100 as shown in FIG. 3E may be obtained by slicing the block body portion 5 into each unit body portion 1.

FIGS. 3A to 3E are perspective views for explaining a method of manufacturing the electric field read/write head 100 of FIG. 1. By modifying the method, the electric field read/write head 100′ of FIG. 2 may be obtained. For example, in the operation of FIG. 3A, the first electrode pad P1 and the second electrode pad P2 of FIG. 2 may be formed instead of the source S1 and the drain D1. In the operation of FIG. 3D, the channel layer C1 may be formed after the source S1′ and the drain D1′ of FIG. 2 are formed, thus manufacturing the electric field read/write head 100′ of FIG. 2. In this case, the elbow type conductive plug may be formed in the unit body portion 1 for the electric connection between the first electrode pad P1 and the source S1′ and between the second electrode pad P2 and the drain D1′. A part of the elbow type conductive plug may be formed before the first and second electrode pads P1 and P2 are formed and the other part thereof may be formed before the source S1′ and the drain D1′ are formed. Also, after the channel layer C1 is formed, the source S1′ and the drain D1′ may be formed to cover both ends of the channel layer C1.

According to exemplary embodiments of the present invention, after the ABS process is performed, the channel layer C1 of a read head is formed on the first face F1 facing the recording medium. If the ABS process is performed after a channel region parallel to the second face F2 is formed in an upper portion of the body portion 1 or on the second face F2, since the channel region undergoes the ABS process, the channel region may be damaged. In this case, the channel region may be formed on the substrate 10 of FIG. 3A. As the substrate 10 is sliced into a bar shape and then undergoes the grinding, lapping, and patterning processes, the channel region may be physically damaged. As a result, the performance of the read head including the channel region is deteriorated.

Actually, for a read head having a metal-oxide-semiconductor field effect transistor (MOSFET) structure, a sensitivity of about 0.15% before the ABS process changes to a sensitivity of about 0.015% after the ABS process. In exemplary embodiments of the present invention however, since the channel layer C1 is formed after the ABS process, the channel layer C1 is not likely to be damaged by the ABS process. Since the write head W1 is a conductive layer that is simply formed of metal, the performance of the write head W1 is hardly deteriorated by the ABS process. Thus, according to exemplary embodiments of the present invention, the electric field read/write head having a high performance read head can be realized.

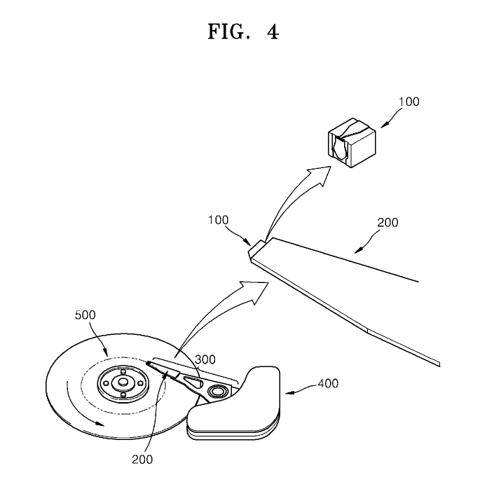

FIG. 4 is a perspective view of an information storage device comprising the electric field read/write head 100 according to an exemplary embodiment of the present invention.

Referring to FIG. 4, the information storage device according to an exemplary embodiment of the present invention includes a recording medium 500 having a recording layer formed of a ferroelectric material and the electric field read/write head 100 recording information on the recording medium 500 and reproducing information from the recording medium 500. Since the electric field read/write head 100 is the same as the electric field read/write head 100 of FIG. 1, a description thereof will be omitted herein. The electric field read/write head 100 of FIG. 4 may be replaced by the electric field read/write head 100′ of FIG. 2 or a head modified therefrom.

In the information storage device, the recording medium 500 is of a rotating disc type and has a lower electrode (not shown) grounded thereunder. The electric field read/write head 100 is attached to a suspension 200 located at an end tip of a swing arm 300 and pivots by flying over the surface of the recording medium 500. A voice coil motor (VCM) 400 rotates the swing arm 300. The operation system of the information storage device according to an exemplary embodiment of the present invention is similar to that of a conventional HDD. Thus, according to an exemplary embodiment of the present invention, an information storage device that is stably driven without a difficulty in system development and has a high recording density of over 1 Tb/in² can be realized.

The principle of reading of the information storage device of FIG. 4 including the electric field read/write head 100 of FIG. 1 will be described below.

When the channel layer C1 of the electric field read/write head 100 is an n⁻ region and the surface charge of the recording medium 500 where the channel layer C1 is located is negative (−), the electron density of the channel layer C1 decreases so that the resistance of the channel layer C1 increases and the current between the source S1 and the drain D1 decreases. Contrarily, when the surface charge of the recording medium 500 where the channel layer C1 is located is positive (+), the electron density of the channel layer C1 increases so that the resistance of the channel layer C1 decreases and the current between the source S1 and the drain D1 increases. By detecting the change in the resistance and current, information recorded on the surface of the recording medium 500 can be read.

The principle of writing of the information storage device of FIG. 4 including the electric field read/write head 100 of FIG. 1 will be described below.

When a positive (+) voltage over a critical voltage is applied to the write head W1 of the electric read/write head 100, since the lower electrode located under the recording medium 500 is 0 V, the surface of the recording medium 500 has a negative (−) polarity. Contrarily, when a negative (−) voltage below the critical voltage is applied to the write head W1 of the electric read/write head 100, since the lower electrode located under the recording medium 500 is 0 V, the surface of the recording medium 500 has a positive (+) polarity. Accordingly, the polarity direction of the electric domain of the recording medium 500 that is ferroelectric varies according to the amount of the voltage applied to the write head W1 so that information can be recorded thereon.

While this invention has been particularly shown and described with reference to exemplary embodiments thereof, it will be understood by those skilled in the art that various changes in form and details may be made therein without departing from the spirit and scope of the invention as defined by the appended claims. For example, one who is skilled in the art to which the present invention pertains can diversely modify the structures of the source S1, the drain D1, and the channel layer C1 of FIG. 1 and the structures of the source S1′, the drain D1′, and the channel layer C1′ of FIG. 2. Also, the head of the present invention can be used as a head dedicated for read without using the write head W1.

What is claimed is:

1. An electric field head comprising:
a body portion; and
a read head comprising a channel layer which is provided on an air bearing surface (ABS) of the body portion which faces a recording medium, a source which contacts a first end of the channel layer, and a drain which contacts a second end of the channel layer.

2. The electric field head of claim 1, further comprising a write head which is provided on a surface of the body portion that is perpendicular to the ABS of the body portion.

3 . The electric field head of claim 1, wherein the channel layer comprises one of carbon nanotube, graphene, and semiconductor nanowire.

4. The electric field head of claim 1, wherein the source and the drain extend from the ABS of the body portion to a surface of the body portion that is perpendicular to the ABS.

5. The electric field head of claim 1, wherein the source and the drain are a metal region or a doping region.

6. The electric field head of claim 1, wherein the source and the drain are a metal layer provided on the ABS of the body portion.

7. The electric field head of claim 1, wherein the source and the drain are a metal layer provided in the ABS of the body portion.

8. A method of manufacturing an electric field head, the method comprising:
defining a head forming portion of a substrate;
separating the head forming portion from other portions of the substrate;
forming an air bearing surface (ABS) pattern on a side surface of the separated head forming portion; and
forming a channel layer for a read head on a surface of the head forming portion where the ABS pattern is formed.

9. The method of claim 8, further comprising forming a write head on the head forming portion before the head forming portion is separated from the other portions of the substrate.

10. The method of claim 8, wherein the head forming portion comprises a plurality of head forming regions.

11. The method of claim 8, wherein the channel layer is formed of one of carbon nanotube, graphene, and semiconductor nanowire.

12. The method of claim 8, wherein the read head comprises a source which contacts a first end of the channel layer and a drain contacts a second end of the channel layer.

13. An information storage device comprising:
a ferroelectric recording medium; and
an electric field head,
wherein the electric field head comprises:
a body portion; and
a read head comprising a channel layer which is provided on an air bearing surface (ABS) of the body portion which faces the ferroelectric recording medium, a source which contacts a first end of the channel layer, and a drain which contacts a second end of the channel layer.

14. The information storage device of claim 13, further comprising a write head which is provided on a surface of the body portion that is perpendicular to the ABS of the body portion.

15. The information storage device of claim 13, wherein the channel layer comprises one of carbon nanotube, graphene, and semiconductor nanowire.

16. The information storage device of claim 13, wherein the source and the drain extend from the ABS of the body portion to a surface of the body portion that is perpendicular to the ABS of the body portion.

17. The information storage device of claim 13, wherein the source and the drain are a metal region or a doping region.

18. The information storage device of claim 13, wherein the source and the drain are a metal layer provided on the ABS surface.

19. The information storage device of claim 13, wherein the source and the drain are a metal layer provided in the ABS surface.

20. The information storage device of claim 13, wherein the ferroelectric recording medium is of a rotating disc type and the electric field head pivots by flying over a surface of the ferroelectric recording medium.
